(19) United States
(12) Patent Application Publication
(10) Pub. No.: US 2022/0076963 A1
(43) Pub. Date: Mar. 10, 2022

(54) SUBSTRATE PROCESSING APPARATUS AND OPERATION METHOD FOR SUBSTRATE PROCESSING APPARATUS

(71) Applicant: EUGENE TECHNOLOGY CO., LTD., Yongin-si (KR)

(72) Inventors: Seung Kook YANG, Yongin-si (KR); Bong Ju JUNG, Yongin-si (KR); Kyu Wan KANG, Yongin-si (KR)

(73) Assignee: EUGENE TECHNOLOGY CO., LTD., Yongin-si (KR)

(21) Appl. No.: 17/469,446

(22) Filed: Sep. 8, 2021

(30) Foreign Application Priority Data
Sep. 8, 2020 (KR) 10-2020-0114927

(51) Int. Cl. H01L 21/324; H01L 21/67

(52) U.S. Cl. CPC H01L 21/324; H01L 21/67109

(57) ABSTRACT

In one embodiment, a method for operating a substrate processing apparatus comprising a chamber in which a fluorine/silicon-containing substance is deposited on an inner wall through an oxide film removal process for a substrate placed therein, and an antenna installed outside the chamber to which RF power is applied, the method comprising: decomposing thermally the fluorine/silicon-containing substance through heating the inner wall of the chamber to 75° C. or more by supplying an inert gas to the inside of the chamber and applying RF power to the antenna.

### BACKGROUND OF THE INVENTION

The present invention relates to a substrate processing apparatus and an operation method for the substrate processing apparatus, and more particularly, to a substrate processing apparatus capable of removing a fluorine/silicon-containing substance deposited on an inner wall of a chamber and an operation method for the substrate processing apparatus.

In the manufacture of semiconductors, displays, solar cells, and other electronics, native oxides are commonly formed on the surface of a substrate when the surface of the substrate is exposed to oxygen and/or atmospheric water. An exposure to the oxygen occurs when substrates are moved between processing chambers at atmospheric or ambient conditions, or when small amounts of oxygen remain in the processing chamber. Also, native oxides may result from contamination during the etching process. Native oxide films are typically very thin, such as 5-20A, but thick enough to generate difficulties in subsequent manufacturing processes. Thus, native oxide layers are typically undesirable and need to be removed prior to subsequent manufacturing processes.

### SUMMARY OF THE INVENTION

The present invention provides a substrate processing apparatus and an operation method for the substrate processing apparatus, a fluorine/silicon-containing substance is deposited on the inner wall of the chamber in the process of removing the oxide on the surface of the substrate and the fluorine/silicon-containing substance can be removed.

Also, the present invention provides a substrate processing apparatus and an operation method for the substrate processing apparatus, a fluorine/silicon-containing substance can be removed In-Situ.

Another object of the present invention will become evident with reference to following detailed descriptions and accompanying drawings.

In one embodiment, a method for operating a substrate processing apparatus comprising a chamber in which a fluorine/silicon-containing substance is deposited on an inner wall through an oxide film removal process for a substrate placed therein, and an antenna installed outside the chamber to which RF power is applied, the method comprising: decomposing thermally the fluorine/silicon-containing substance through heating the inner wall of the chamber to 75° C. or more by supplying an inert gas to the inside of the chamber and applying RF power to the antenna.

The inert gas can be argon.

Applying RF power to the antenna can comprise supplying RF power during a supply time and stopping RF power during a stop time, supplying RF power and stopping RF power time are periodically repeated.

The supply time can be longer than the stop time.

The method can further comprise: reacting with an oxide film formed on the surface of the substrate through supplying a reactive gases to the surface of the substrate, the reactive gases are generated from a source gas by supplying the source gas to the inside of the chamber and applying RF power to the antenna, in a state in which a substrate is placed on a substrate support; transferring the substrate to an annealing chamber by taking the substrate out of the chamber; and heating the substrate to 80° C. or more in an annealing chamber, wherein decomposing thermally the fluorine/silicon-containing substance can be accomplished after heating the substrate.

In one embodiment, a substrate processing apparatus comprises: a chamber having an inner space; a substrate support installed in the inner space on which a substrate is placed; an antenna installed outside the chamber to which RF power is applied; a gas supply unit capable of supplying an inert gas and a source gas to the inside of the chamber; and a controller electrically connected to the gas supply unit and the antenna to apply RF power to the antenna, wherein the controller has a cleaning mode, so that the inert gas is supplied to the inside of the chamber and RF power is applied to the antenna in the cleaning mode, thereby heating the inner wall of the chamber to 75° C. or more and decomposing thermally the fluorine/silicon-containing substance.

According to the embodiment of the present invention, the temperature of the inner wall of the chamber can be increased by generating plasma from the inert gas with an antenna installed outside the chamber, and thus the fluorine/silicon-containing substance deposited on the inner wall of the chamber can be removed.

Especially, the antenna is provided to generate a reactive gas from the source gas in the process of removing the oxide, so that it is possible to increase the temperature of the chamber inner wall through the antenna without a heating device and to remove the fluorine/silicon-containing substance deposited on the chamber inner wall In-Situ.

### BRIEF DESCRIPTION OF THE DRAWINGS

FIG. 1 illustrates a substrate processing apparatus according to an embodiment of the present invention.

FIG. 2 illustrates a supply time of a source gas and an inert gas and a supply time of RF power.

FIG. 3 is a graph illustrating a temperature variation of an inner wall of a chamber according to RF power.

### DETAILED DESCRIPTION OF PREFERRED EMBODIMENTS

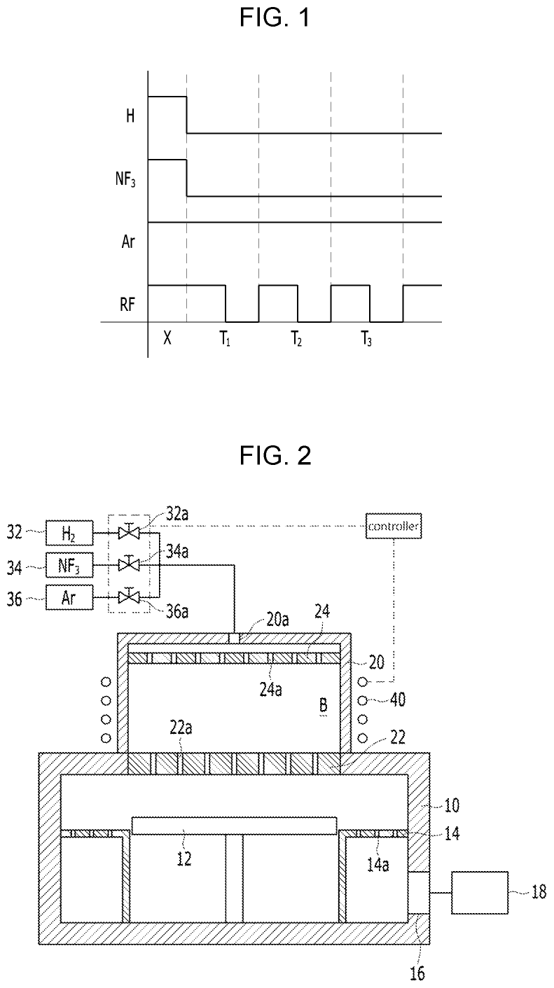

Hereinafter, exemplary embodiments of the present invention will be described in detail with reference to FIGS. 1 to 3. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

First, the oxygenation on the surface of the substrate S may, for example, occur when the substrate is exposed to the atmosphere while the substrate is transferred. Thus, the cleaning process for removing a native oxide (or surface oxide) formed on the substrate is required.

The cleaning process may be a dry etching process using hydrogen (H*) and NF₃ gases having a radical state. For example, when the silicon oxide formed on the surface of the substrate is etched, the substrate is disposed within a chamber, and then a vacuum atmosphere is formed within the chamber to generate an intermediate product reacting with the silicon oxide within the chamber.

For example, when radicals (H*) of a hydrogen gas and a reaction gas such as a fluoride gas (for example, nitrogen fluoride (NF₃)) are supplied into the chamber, the reaction gases are reduced as expressed in following reaction formula (1) to generate an intermediate product such as NHₓF_{y} (where x and y are certain integers).

H*+NF₃⇒NHₓF_{y} (1)

Since the intermediate product has high reactivity with silicon oxide (SiO₂), when the intermediate product reaches a surface of the silicon substrate, the intermediate product selectively reacts with the silicon oxide to generate a reaction product ((NH₄)₂SiF₆) as expressed in following reaction formula (2).

NHₓF_{y}+SiO₂⇒(NH₄)₂SiF₆+H₂O (2)

Thereafter, when the silicon substrate is heated as a temperature of about 100° C. or more, the reaction product is pyrolyzed as expressed in following reaction formula (3) to form a pyrolysis gas, and then the pyrolysis gas is evaporated. As a result, the silicon oxide may be removed from the surface of the substrate. As shown in the following reaction formula (3), the pyrolysis gas includes a gas containing fluorine such as an HF gas or a SiF₄ gas.

(NH₄)₂SiF₆⇒NH₃+HF+SiF₄ (3)

As described above, the cleaning process may include a reaction process for generating the reaction product and a heating process for pyrolyzing the reaction product. The reaction process and the heating process may be performed at the same time within the cleaning chambers 108a and 108b. Alternatively, the reaction process may be performed within one of the cleaning chambers 108a and 108b, and the heating process may be performed within the other one of the cleaning chambers 108a and 108b.

FIG. 1 illustrates a substrate processing apparatus according to an embodiment of the present invention. The substrate processing apparatus includes a reaction chamber, which includes a lower chamber 10 and an upper chamber 20. The intermediate products and the reaction products are generated in the reaction chamber, and then the substrate is transferred to an annealing chamber, and then an annealing process is performed in the annealing chamber.

The upper chamber 20 is installed above the lower chamber 10, the lower chamber 10 has a reaction space A formed therein, and the upper chamber 20 has a generation space B formed therein. The reaction space A communicates with the generation space B through openings respectively formed in the upper portion of the lower chamber 10 and the lower portion of the upper chamber 20.

The substrate support 12 is installed inside the lower chamber 10, and the substrate may be placed on the upper portion of the substrate support 12 after being loaded in the lower chamber 10 through a passage (not shown) formed on the sidewall of the lower chamber 10. The baffle 14 has a ring shape and is installed around the substrate support 12. The baffle 14 is supported through the baffle support and is positioned lower than the upper surface of the substrate support 12, and the by-products in the reaction space A move to the exhaust port 16 through the baffle hole 14a. The vacuum pump 18 is connected to the exhaust port 16 to forcibly discharge the by-products and the like to the outside of the reaction chamber.

The diffusion plate 22 is installed between the reaction space A and the generation space B, and substances (eg, intermediate products, etc.) generated in the generation space B are move to the reaction space A through the diffusion hole 22a formed in the diffusion plate 22.

The injection plate 24 is installed in the upper portion of the generating space B and spaced apart from the ceiling surface of the upper chamber 20, and the source gas and the inert gas are supplied to an upper space of the injection plate 24 through the supply hole 20a. The injection plate 24 has a plurality of injection holes 24a, and the source gas and the inert gas may move to a lower space of the injection plate 24 through the injection holes 24a.

Gases stored in gas supply sources 32, 34, and 36 move to the supply hole 20a through the respective flow controllers 32a, 34a, and 36a, and the flow controllers 32a, 34a, and 36a can control(or block) the flow rate of the gases. The gas supply sources 32, 34, and 36 may include a hydrogen supply source 32, a nitrogen fluoride supply source 34, and an argon gas supply source 36.

The antenna 40 has a cylindrical shape and is installed around the upper chamber 20 in the vertical direction. The antenna 40 is electrically connected to an RF power supply source through the controller 50, and the controller 50 may adjust the RF power supplied to the antenna 40. In addition, the controller 50 may be electrically connected to the flow controllers 32a, 34a, and 36a to adjust the flow rate of the gases moving to the supply hole 20a.

FIG. 2 illustrates a supply time of a source gas and an inert gas and a supply time of RF power. Hereinafter, an operating method of the substrate processing apparatus will be described with reference to FIGS. 1 and 2.

The substrate moves into the lower chamber 10 and is placed on the substrate support 12, and the substrate is disposed parallel to the upper surface of the substrate support 12.

Then, using the controller 50, the source gases, namely, hydrogen and nitrogen fluoride from the hydrogen source (eg, ammonia(NH3), H2O, etc.) 32 and the nitrogen fluoride source 34 are supplied to the generation space B (section ‘X’ in FIG. 2). At this time, argon as an inert gas may be supplied to the generation space B from the argon gas supply source 36 to be added to hydrogen and nitrogen fluoride, and argon may be replaced with another inert gas.

In addition, RF power may be applied to the antenna 40 through the controller 50 (section ‘X’ in FIG. 2), and the RF power may be about 500 W. Through this process, the source gas is dissociated in the generation space B to form an intermediate product (a reactive gas)(for example, fluoride ammonium (NH4F) or hydrogen fluoride ammonium (NH4F(HF))), the intermediate product moves to the reaction space A through the diffusion hole 22 so as to react with the surface of the substrate containing silicon oxide.

Thereafter, the reactive gas (eg, fluoride ammonium (NH4F)) as an intermediate product reacts with silicon oxide on the surface of the substrate in the reaction space A to form ammonium hexafluorosilicate((NH4)2SiF6), ammonia, water, etc., and ammonia and water may be removed from the reaction chamber by a vacuum pump 18.

Thereafter, the substrate is transferred from the reaction chamber to the annealing chamber, and when the substrate is heated to 80° C. or more in the annealing chamber, the ammonium hexafluorosilicate can be decomposed into volatile components such as ammonia, hydrogen fluoride, etc. or sublimated. The annealing chamber is purged and evacuated.

Meanwhile, as described above, the reactive gas, which is an intermediate product, reacts with silicon oxide on the surface of the substrate in the reaction space A to generate ammonium hexafluorosilicate ((NH4)₂SiF6) as a reaction product, and in this process, the reaction product is generated not only on the substrate surface but also on the inner wall of the reaction chamber. Especially, since such reaction products fall off or float to act as contaminants in a future reaction process, a chamber cleaning process to remove them is periodically required (based on about 20,000 times).

In the conventional chamber cleaning method, a cleaning gas containing fluorine (F) is supplied to the inside of the chamber, but the reaction product is not removed through the cleaning gas because the reaction product is a fluorine/silicon-containing substance.

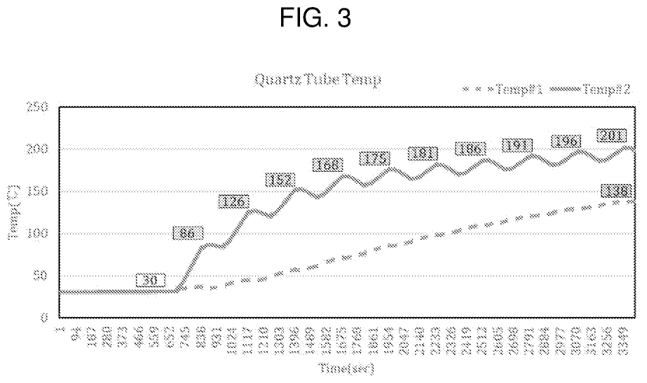

FIG. 3 is a graph illustrating a temperature variation of an inner wall of a chamber according to RF power. The controller 50 may operate in the cleaning mode (section ‘T1, T2, . . . ’ in FIG. 2) after the above-described reaction mode (section ‘X’ in FIG. 2) is terminated and the substrate is removed from the reaction chamber. Hereinafter, a cleaning mode will be described with reference to FIG. 3.

First, using the controller 50, the flow controllers 32a and 34a for the source gas are closed to block the supply of the source gas, and the flow controller 36a for the argon gas is opened to supply argon gas to the space B (‘T1’ section in FIG. 2). The supply amount of argon gas may be 1,500 to 2,500 sccm, preferably 2,000 sccm.

In addition, RF power may be supplied to the antenna 40 through the controller 50 (section ‘T1’ in FIG. 2), and the RF power may be about 2,000 W (pressure in the reaction chamber=1 Torr). RF power may be supplied for about 150 seconds, and then RF power may be cut off for about 100 seconds.

As shown in FIG. 3, plasma is generated in the generation space B from the argon gas through this process, and thus the temperature of the generation space B increases. That is, the generation space B can be heated by generating plasma through the argon gas, and in particular, the temperature increase of the generation space B is greatly increased in the portion close to the antenna 40. In this case, after a supply time of supplying the RF power, a stop time for cutting off the RF power is required, and the stop time has a meaning of a reaction time required to increase the temperature of the generation space B increases due to the plasma generation.

As shown in FIGS. 2 and 3, the cleaning mode is repeated several times until the temperatures Temp#1/Temp#2 of the generation space B reach a desired temperature (section ‘T1, T2, . . . ’ in FIG. 2)), the time required for one cycle is about 250 seconds. The controller 50 finally cuts off the RF power when the temperatures (Temp#1/Temp#2) of the generation space B reach a desired temperature, and the temperatures (Temp#1/Temp#2) of the generation space (B) are can be measured through a temperature sensing device (not shown) installed on the inner wall of the upper chamber 20.

Through this process, the temperature (Temp#1/Temp#2) of the generation space B can gradually increase to reach about 150° C. (if repeated 10 times, it rises to 201° C.), and the reaction product formed on the inner wall of the generation space B may be decomposed into volatile components or sublimed and then forcibly discharged to the outside of the reaction chamber through the exhaust port 16.

As described above, it is possible to heat the generation space B in a manner that generates plasma through the argon gas, and through this, the reaction product formed on the inner wall of the generation space B and the like can be removed. In particular, since this method does not significantly affect the temperature of the substrate support 12, it is not necessary to cool the substrate support 12 for a subsequent process after cleaning the reaction chamber.

Meanwhile, in this embodiment, argon is adopted as the carrier/purge gas, and the reaction chamber is cleaned with argon, but argon may be replaced with other inert gas.

Although the present invention is described in detail with reference to the exemplary embodiments, the invention may be embodied in many different forms. Thus, technical idea and scope of claims set forth below are not limited to the preferred embodiments.

What is claimed is:

1. A method for operating a substrate processing apparatus comprising a chamber in which a fluorine/silicon-containing substance is deposited on an inner wall through an oxide film removal process for a substrate placed therein, and an antenna installed outside the chamber to which RF power is applied, the method comprising:
decomposing thermally the fluorine/silicon-containing substance through heating the inner wall of the chamber to 75° C. or more by supplying an inert gas to the inside of the chamber and applying RF power to the antenna.

2. The method of claim 1, wherein the inert gas is argon.

3. The method of claim 1, wherein applying RF power to the antenna comprises supplying RF power during a supply time and stopping RF power during a stop time, supplying RF power and stopping RF power time are periodically repeated.

4. The method of claim 3, wherein the supply time is longer than the stop time.

5. The method of claim 1, the method further comprising:
reacting with an oxide film formed on the surface of the substrate through supplying a reactive gases to the surface of the substrate, the reactive gases are generated from a source gas by supplying the source gas to the inside of the chamber and applying RF power to the antenna, in a state in which a substrate is placed on a substrate support;
transferring the substrate to an annealing chamber by taking the substrate out of the chamber; and
heating the substrate to 80° C. or more in an annealing chamber,
wherein decomposing thermally the fluorine/silicon-containing substance is accomplished after heating the substrate.

6. A substrate processing apparatus comprising:
a chamber having an inner space;
a substrate support installed in the inner space on which a substrate is placed;
an antenna installed outside the chamber to which RF power is applied;
a gas supply unit capable of supplying an inert gas and a source gas to the inside of the chamber; and
a controller electrically connected to the gas supply unit and the antenna to apply RF power to the antenna,
wherein the controller has a cleaning mode, so that the inert gas is supplied to the inside of the chamber and RF power is applied to the antenna in the cleaning mode, thereby heating the inner wall of the chamber to 75° C. or more and decomposing thermally the fluorine/silicon-containing substance.
